(19) United States
(12) Patent Application Publication
(10) Pub. No.: US 2022/0049604 A1
(43) Pub. Date: Feb. 17, 2022

(54) Shale gas well dynamic production allocating method

(71) Applicant: Southwest Petroleum University, Chengdu (CN)

(72) Inventors: Shuyong Hu, Chengdu (CN); Tingting Qiu, Chengdu (CN); Boning Zhang, Chengdu (CN); Jiatie Zhang, Chengdu (CN); Xindong Wang, Chengdu (CN); Wenhai Huang, Chengdu (CN)

(21) Appl. No.: 17/099,562

(22) Filed: Nov. 16, 2020

(30) Foreign Application Priority Data
Aug. 12, 2020 (CN) 202010810619.4

(51) Int. Cl. E21B 49/00

(52) U.S. Cl. CPC E21B 49/008; E21B 47/06; E21B 49/006

(57) ABSTRACT

The present invention provides a shale gas well dynamic production allocating method. The steps comprise: step 1, constructing a single well material balance equation of a shale gas well; step 2, according to the actual shale gas well related reservoir properties, establishing the relationship function between the cumulative gas production and the formation pressure in combination with constructing a single well actual material balance equation in step 1; step 3, calculating the cumulative gas production according to the current formation pressure; step 4, through the productivity test, establishing a binomial productivity equation, and allocating production according to the open flow; step 5, according to the production allocating result obtained in step 4, drawing a chart of cumulative gas production and formation pressure and single well production allocation; and step 6, according to the cumulative gas production of different reservoirs of a shale gas well, searching for the resulting chart for production allocation. The solution of the present invention can not only quickly allocate production. In the production process of a gas well, according to the current cumulative gas production of the well, a reasonable production allocation amount can be quickly determined by searching for the chart, and there is no need to consider time factors in the production allocating process, which is very convenient, efficient, and practical.

### TECHNICAL FIELD

The present invention belongs to the technical field of shale gas exploration and development, and specifically relates to a shale gas well dynamic production allocating method.

### BACKGROUND

In the process of shale gas exploration and development, conventional shale gas production allocating methods (such as decreasing curve analysis methods) have large prediction errors and complex production allocation processes.

In addition, the document CN104948163B discloses a shale gas well productivity measuring method, the steps comprises: testing, collecting and setting gas reservoir engineering parameters, and establishing a gas well productivity equation; considering the desorption and diffusion of adsorbed gas, establishing material balance equations for shale gas reservoirs in the fracturing transformation areas and non-fracturing transformation areas of gas wells; calculating the initial production of the gas well at the initial time according to the gas well productivity equation, respectively; setting the time step, calculating the time corresponding to the next time step, and updating the current time step; iteratively calculating the average formation pressure in the fracturing transformation area at the current time step according to the material balance equation of the shale gas reservoir in the fracturing transformation area; iteratively calculating the average formation pressure in the non-fracturing transformation area at the current time step according to the average formation pressure in the fracturing transformation area at the current time step and the material balance equation of the shale gas reservoir in the non-fracturing transformation area; calculating the shale gas well productivity at the current time step according to the average formation pressure in the fracturing transformation area and the non-fracturing transformation area at the current time step; and judging whether the current time is greater than the given maximum evaluation days: if so, outputting the calculation result of shale gas well productivity. The document CN106484933B discloses a method and system for determining the well-controlled dynamic reserves of a shale gas well. The method comprises: obtaining the original formation pressure of the shale gas reservoir, and calculating the shaft bottom flow pressure based on the gas well structure data and production data; establishing a first interpolation table based on the conversion relationship between the pressure and the pseudo-pressure to establish the corresponding relationship between the pressure p and the pseudo-pressure m(p); establishing a second interpolation table based on the given basic parameters and Za(p) defined by the shale gas reservoir material balance equation to establish the corresponding relationship between pressure p and the ratio between pressure p and Za(p); and based on the original formation pressure, the shaft bottom pressure and the production data, using the first interpolation table, the second interpolation table and the productivity equation to determine the well-controlled dynamic reserves of a shale gas well; in this method, production time needs to be converted into material balance pseudo time.

However, in shale gas production sites and production stages, it is often necessary to quickly allocate production to shale gas wells. Although the production allocating method described above can meet the production requirements, it can only provide production allocation to current production data, or it is necessary to carry out calculations for a specific time multiple times. The production allocation process is still complicated, and the production allocation efficiency is still low.

### SUMMARY

The object of the present invention is to provide a shale gas well dynamic production allocating method with simple production allocation process, high production allocation efficiency without considering time factors.

In order to achieve the above object, the present invention adopts the following technical solutions.

A shale gas well dynamic production allocating method, wherein the steps comprise:

step 1, constructing a single well material balance equation of a shale gas well, wherein

when the adsorbed gas is not desorbed, the material balance equation refers to formula (I);

$${G}_{pg} {B}_{g} + {G}_{pw} {B}_{w} = {G}_{m} ( {B}_{g} - {B}_{gi} ) + {G}_{m} {B}_{gi} \frac{{c}_{w} {S}_{mwi}}{1 - {S}_{mwi}} ( {P}_{i} - P ) + {G}_{m} {B}_{gi} \frac{{c}_{m}}{1 - {S}_{mwi}} ( {P}_{i} - P ) + \frac{{G}_{m} {B}_{gi}}{( 1 - {S}_{mwi} ) {B}_{w}} {S}_{mwi} ( {R}_{si} - {R}_{s} ) {B}_{g} + {G}_{f} ( {B}_{g} - {B}_{gi} ) + {G}_{f} {B}_{gi} \frac{{c}_{w} {S}_{fwi}}{1 - {S}_{fwi}} ( {P}_{i} - P ) + {G}_{f} {B}_{gi} \frac{{c}_{f}}{1 - {S}_{mwi}} ( {P}_{i} - P ) + \frac{{G}_{f} {B}_{gi}}{( 1 - {S}_{fwi} ) {B}_{w}} {S}_{fwi} ( {R}_{si} - {R}_{s} ) {B}_{g} \qquad ( I )$$

when the adsorbed gas is desorbed, the material balance equation refers to formula (II);

$${G}_{p g} {B}_{g} + {C}_{pw} {B}_{w} = {G}_{m} ( {B}_{g} - {B}_{gi} ) + {G}_{m} {B}_{gi} \frac{{c}_{w} {S}_{mwi}}{1 - {S}_{mwi}} ( {P}_{i} - P ) + {G}_{m} {B}_{gi} \frac{{c}_{m}}{1 - {S}_{mwi}} ( {P}_{i} - P ) + \frac{{G}_{m} {B}_{gi}}{( 1 - {S}_{mwi} ) {B}_{w}} {S}_{mwi} ( {R}_{si} - {R}_{s} ) {B}_{g} + {G}_{f} ( {B}_{g} - {B}_{gi} ) + {G}_{f} {B}_{gi} \frac{{c}_{w} {S}_{fwi}}{1 - {S}_{fwi}} ( {P}_{i} - P ) + {G}_{f} {B}_{gi} \frac{{c}_{f}}{1 - {S}_{mwi}} ( {P}_{i} - P ) + \frac{{G}_{f} {B}_{gi}}{( 1 - {S}_{fwi} ) {B}_{w}} {S}_{fwi} ( {R}_{si} - {R}_{s} ) {B}_{g} + {ρ}_{s} {V}_{S} {V}_{m} ( \frac{{P}_{c d}}{{P}_{L} + {P}_{c d}} - \frac{P}{{P}_{L} + P} ) \qquad ( II )$$

in formula (I) and formula (II):

Gₘ represents the surface free gas volume of shale gas reservoir matrix, G_{f} represents the surface free gas volume of shale gas reservoir fractures, B_{gi} represents the original volume coefficient of shale gas, C_{w} represents the groundwater compression coefficient of a shale gas reservoir, Cₘ represents the compression coefficient of shale matrix, Rₛᵢ represents the original groundwater solubility coefficient of a shale gas reservoir, Pᵢ represents the original formation pressure, S_{wf} represents the fracture water saturation of a shale gas reservoir, C_{f} represents the fracture rock compressibility coefficient, B_{w} represents the formation water volume coefficient, ρₛ represents the shale density, Vₘ represents the Langmuir's volume, P_{L} represents the Langmuir's pressure, P_{cd} represents the critical desorption pressure, Vₛ represents the single well controlled shale volume, B_{g} represents the natural gas volume coefficient, Rₛ represents the formation water solubility coefficient, Rₛ represents the original groundwater solubility coefficient, P represents the formation pressure, G_{pg} represents the cumulative gas production, G_{pw} represents the cumulative water production, S_{mwi} represents the original water saturation of the matrix, and S_{fwi} represents the original water saturation of the fracture;

step 2, according to the actual shale gas well related reservoir properties, establishing the relationship function between the cumulative gas production and the formation pressure in combination with constructing a single well actual material balance equation in step 1;

step 3, calculating the cumulative gas production according to the current formation pressure;

step 4, according to the current formation pressure, through the productivity test, establishing a binomial productivity equation, and allocating production according to the open flow;

step 5, according to the production allocating result obtained in step 4, drawing a chart of cumulative gas production and formation pressure and single well production allocation; and

step 6, according to the cumulative gas production of different reservoirs of a shale gas well, searching for the resulting chart for production allocation.

As a preferred solution, the chart drawn in step 5 comprises a double-logarithmic diagram of pressure and cumulative gas production before desorption, a double-logarithmic diagram of production allocation and cumulative gas production before desorption, a double-logarithmic diagram of pressure and cumulative gas production after desorption, a double-logarithmic diagram of production allocation and cumulative gas production after desorption, and the full life cycle production allocating chart of a shale gas well is drawn based on these four charts.

The present invention has the following beneficial effects.

For shale gas wells, the solution of the present invention constructs a brand-new material balance equation, which can not only quickly allocate production. In the production process of a gas well, according to the current cumulative gas production of the well, a reasonable production allocation amount can be quickly determined by searching for the chart. Production allocation can be completed within one minute, and there is no need to consider time factors in the production allocating process, which is very convenient, efficient, and practical; the solution of the present invention can also be used to predict formation pressure in the reverse direction, predict EUR according to current production rules, and can amend the chart of this solution based on the actual production data so that the production allocation is more realistic; in addition, the physical parameters of the gas well formation rock and the fluid are obtained in the reverse direction according to the actual production data of the shale gas well in this solution.

### BRIEF DESCRIPTION OF THE DRAWINGS

FIG. 1 is a double-logarithmic diagram of pressure and cumulative gas production before desorption in the embodiment;

FIG. 2 is a double-logarithmic diagram of production allocation and cumulative gas production before desorption in the embodiment;

FIG. 3 is a double-logarithmic diagram of pressure and cumulative gas production after desorption in the embodiment;

FIG. 4 is a double-logarithmic diagram of production allocation and cumulative gas production after desorption in the embodiment;

FIG. 5 is a double-logarithmic diagram of pressure and cumulative gas production in the embodiment;

FIG. 6 is a double-logarithmic diagram of production allocation and cumulative gas production in the embodiment;

FIG. 7 is a double-logarithmic implementation diagram of actual production allocation in the embodiment.

### DESCRIPTION OF THE EMBODIMENTS

The technical solutions of the present invention will be further described hereinafter in combination. It is pointed out that the following embodiments cannot be understood as limiting the scope of protection of the present invention. Those skilled in the art make some non-essential improvements and adjustments based on the claims of the present invention, all of which fall within the protection scope of the present invention.

### Embodiment

A shale gas well dynamic production allocating method is provided, wherein the steps are as follows.

The obtained relevant parameters of a certain shale gas well are shown in Table 1.

TABLE 1
Parameters of a certain shale gas well

| | | | | Parameter |
|---|---|---|---|---|
| Parameter name | Symbol | Unit | Parameter value | classification |
| surface free gas volume of | Gₘ | m³ | Gₘ + G_{f} = 1.97 × 10⁷ | gas reservoir |
| shale gas reservoir matrix | | | | geological |
| surface free gas volume of | G_{f} | m³ | | parameters |
| shale gas reservoir fractures | | | | |
| original volume coefficient | B_{gi} | m³/m³ | 0.0069 | |
| of shale gas | | | | |
| groundwater compression | C_{w} | Mpa⁻¹ | 0.000453 | |
| coefficient of a shale gas | | | | |
| reservoir | | | | |
| compression coefficient of | Cₘ | Mpa⁻¹ | 0.000419 | |
| shale matrix | | | | |
| original groundwater | Rₛᵢ | m³/m³ | 0.647887 | |
| solubility coefficient of a | | | | |
| shale gas reservoir | | | | |
| original formation pressure | Pᵢ | m³/m³ | 48.6 | |
| fracture water saturation of a | S_{wf} | % | 45 | |
| shale gas reservoir | | | | |
| fracture rock compressibility | C_{f} | Mpa⁻¹ | 0.000419 | |
| coefficient | | | | |
| formation water volume | B_{w} | m³/m³ | 0.993262 | |
| coefficient | | | | |
| shale density | ρ ₛ | g/cm³ | 2.65 | |
| Langmuir's volume | Vₘ | m³ | 3.24 | |
| Langmuir's pressure | P_{L} | MPa | 2.69 | |
| critical desorption pressure | P_{cd} | MPa | 8.67 | |
| single well controlled shale | Vₛ | M³ | 4382 × 104 | |
| volume | | | | |
| natural gas volume | B_{g} | m³/m³ | variable | |
| coefficient | | | | |
| formation water solubility | Rs | m³/m³ | variable | |
| coefficient | | | | |
| Binomial productivity | A | dimensionless | 1.8633 × 10⁻⁸ | gas well test |
| equation coefficient | | | | parameters |
| Binomial productivity | B | dimensionless | 5.78 × 10⁻³ | |
| equation coefficient | | | | |

Step 1, a single well material balance equation of a shale gas well is constructed, wherein

when the adsorbed gas is not desorbed, the material balance equation refers to formula (I);

$${G}_{pg} {B}_{g} + {G}_{pw} {B}_{w} = {G}_{m} ( {B}_{g} - {B}_{gi} ) + {G}_{m} {B}_{gi} \frac{{c}_{w} {S}_{mwi}}{1 - {S}_{mwi}} ( {P}_{i} - P ) + {G}_{m} {B}_{gi} \frac{{c}_{m}}{1 - {S}_{mwi}} ( {P}_{i} - P ) + \frac{{G}_{m} {B}_{gi}}{( 1 - {S}_{mwi} ) {B}_{w}} {S}_{mwi} ( {R}_{si} - {R}_{s} ) {B}_{g} + {G}_{f} ( {B}_{g} - {B}_{gi} ) + {G}_{f} {B}_{gi} \frac{{c}_{w} {S}_{fwi}}{1 - {S}_{fwi}} ( {P}_{i} - P ) + {G}_{f} {B}_{gi} \frac{{c}_{f}}{1 - {S}_{mwi}} ( {P}_{i} - P ) + \frac{{G}_{f} {B}_{gi}}{( 1 - {S}_{fwi} ) {B}_{w}} {S}_{fwi} ( {R}_{si} - {R}_{s} ) {B}_{g} \qquad ( I )$$

when the adsorbed gas is desorbed, the material balance equation refers to formula (II);

$${G}_{p g} {B}_{g} + {C}_{pw} {B}_{w} = {G}_{m} ( {B}_{g} - {B}_{gi} ) + {G}_{m} {B}_{gi} \frac{{c}_{w} {S}_{mwi}}{1 - {S}_{mwi}} ( {P}_{i} - P ) + {G}_{m} {B}_{gi} \frac{{c}_{m}}{1 - {S}_{mwi}} ( {P}_{i} - P ) + \frac{{G}_{m} {B}_{gi}}{( 1 - {S}_{mwi} ) {B}_{w}} {S}_{mwi} ( {R}_{si} - {R}_{s} ) {B}_{g} + {G}_{f} ( {B}_{g} - {B}_{gi} ) + {G}_{f} {B}_{gi} \frac{{c}_{w} {S}_{fwi}}{1 - {S}_{fwi}} ( {P}_{i} - P ) + {G}_{f} {B}_{gi} \frac{{c}_{f}}{1 - {S}_{mwi}} ( {P}_{i} - P ) + \frac{{G}_{f} {B}_{gi}}{( 1 - {S}_{fwi} ) {B}_{w}} {S}_{fwi} ( {R}_{si} - {R}_{s} ) {B}_{g} + {ρ}_{s} {V}_{S} {V}_{m} ( \frac{{P}_{c d}}{{P}_{L} + {P}_{c d}} - \frac{P}{{P}_{L} + P} ) \qquad ( II )$$

in formula (I) and formula (II):

Gₘ represents the surface free gas volume of shale gas reservoir matrix, G_{f} represents the surface free gas volume of shale gas reservoir fractures, B_{gi} represents the original volume coefficient of shale gas, C_{w} represents the groundwater compression coefficient of a shale gas reservoir, Cₘ represents the compression coefficient of shale matrix, Rₛᵢ represents the original groundwater solubility coefficient of a shale gas reservoir, Pᵢ represents the original formation pressure, S_{wf} represents the fracture water saturation of a shale gas reservoir, C_{f} represents the fracture rock compressibility coefficient, B_{w} represents the formation water volume coefficient, ρₛ represents the shale density, Vₘ represents the Langmuir's volume, P_{L} represents the Langmuir's pressure, Pea represents the critical desorption pressure, Vₛ represents the single well controlled shale volume, B_{g} represents the natural gas volume coefficient, Rₛ represents the formation water solubility coefficient, Rₛ represents the original groundwater solubility coefficient, P represents the formation pressure, G_{pg} represents the cumulative gas production, G_{pw} represents the cumulative water production, S_{mwi} represents the original water saturation of the matrix, and S_{fwi} represents the original water saturation of the fracture;

Step 2, according to the actual shale gas well related reservoir properties, the relationship function between the cumulative gas production and the formation pressure is established in combination with constructing a single well actual material balance equation in step 1.

Because the value of accumulated underground water production is too small, the value of accumulated underground water production is ignored. Therefore, when the adsorbed gas is not desorbed (before desorption), the actual material balance equation for a single well is established as formula (III):

$${G}_{pg} {B}_{g} = {G}_{m} ( {B}_{g} - {B}_{gi} ) + {G}_{m} {B}_{gi} \frac{{c}_{w} {S}_{mwi}}{1 - {S}_{mwi}} ( {P}_{i} - P ) + {G}_{m} {B}_{gi} \frac{{c}_{m}}{1 - {S}_{mwi}} ( {P}_{i} - P ) + \frac{{G}_{m} {B}_{gi}}{( 1 - {S}_{mwi} ) {B}_{w}} {S}_{mwi} ( {R}_{si} - {R}_{s} ) {B}_{g} + {G}_{f} ( {B}_{g} - {B}_{gi} ) + {G}_{f} {B}_{gi} \frac{{c}_{w} {S}_{fwi}}{1 - {S}_{fwi}} ( {P}_{i} - P ) + {G}_{f} {B}_{gi} \frac{{c}_{f}}{1 - {S}_{mwi}} ( {P}_{i} - P ) + \frac{{G}_{f} {B}_{gi}}{( 1 - {S}_{fwi} ) {B}_{w}} {S}_{fwi} ( {R}_{si} - {R}_{s} ) {B}_{g} \qquad ( III )$$

[symbol]

[symbol]

[symbol]

[symbol]

where B_{g}=0.22919P^{-0.902}

From the high-pressure physical property parameter test of shale gas in this block, the function relationship between the volume coefficient of natural gas and the formation pressure is obtained by linear regression.

According to Empirical Formula For Formation Water-Related Physical Property Parameters from Chen Yuanqian (Chen Yuanqian, Empirical Formula For Formation Water-Related Physical Property Parameters [J]. Trial Mining Technology, 1990,11 (3):31-33.)

Rₛ=(T,M,P)=−3.1670×10⁻¹⁰T²·M+1.997×10⁻⁸T·M+1.0635×10⁻¹⁰P²·M−9.7764×10⁻⁸P·M+2.9745×10⁻¹⁰T·P·M+1.6230×10⁻⁴T²−2.7879×10⁻²T− . . . 2.0587×10⁻⁵P²+1.7323×10⁻²P+9.5233×10⁻⁶T·P+1.1937 (IV)

In formula (IV): Rₛ—the solubility of natural gas in formation water, m³/m³; T-temperature, ° C.; P-pressure, MPa×10; M-formation water mineralization, mg/L.

Formula (IV) is substituted into the material balance equation (III), and the cumulative gas production is calculated according to different pressures, as shown in Table 2.

TABLE 2
Various parameter values of material balance before desorption

| | | Natural | Formation | Formation | |
|---|---|---|---|---|---|
| | | gas | water | water | Rock |
| | Cumulative | elasticity | elasticity | dissolution | elasticity |
| Formation | gas | gas | gas | gas | gas |
| pressure | production | production | production | production | production |
| (MPa) | (m³) | (m³) | (m³) | (m³) | (m³) |
| 42 | 2560459.20 | 19126.88 | 332.66 | 10.15 | 683.46 |
| 40 | 3336274.03 | 26103.11 | 433.46 | 13.82 | 890.56 |
| 38 | 4112330.29 | 33775.96 | 534.27 | 17.83 | 1097.67 |
| 36 | 4888812.02 | 42257.42 | 635.08 | 22.26 | 1304.78 |
| 34 | 5665925.73 | 51685.15 | 735.88 | 27.16 | 1511.89 |
| 32 | 6443904.57 | 62230.28 | 836.69 | 32.61 | 1719.00 |
| 30 | 7223013.61 | 74108.31 | 937.49 | 38.73 | 1926.10 |
| 28 | 8003556.54 | 87594.61 | 1038.30 | 45.65 | 2133.21 |
| 26 | 8785884.37 | 103046.90 | 1139.10 | 53.54 | 2340.32 |
| 24 | 9570406.94 | 120938.80 | 1239.91 | 62.64 | 2547.43 |
| 22 | 10357608.40 | 141911.19 | 1340.72 | 73.27 | 2754.53 |
| 21 | 10752390.42 | 153817.76 | 1391.12 | 79.28 | 2858.09 |
| 20 | 11148068.55 | 166853.94 | 1441.52 | 85.85 | 2961.64 |
| 19 | 11544735.14 | 181191.83 | 1491.92 | 93.05 | 3065.20 |
| 18 | 11942493.03 | 197040.76 | 1542.33 | 101.01 | 3168.75 |
| 17 | 12341457.31 | 214657.93 | 1592.73 | 109.82 | 3272.30 |
| 16 | 12741757.64 | 234363.14 | 1643.13 | 119.67 | 3375.86 |
| 15 | 13143541.06 | 256559.08 | 1693.54 | 130.73 | 3479.41 |
| 14 | 13546975.68 | 281760.31 | 1743.94 | 143.27 | 3582.97 |
| 13 | 13952255.33 | 310635.31 | 1794.34 | 157.60 | 3686.52 |
| 12 | 14359605.84 | 344069.08 | 1844.74 | 174.15 | 3790.07 |
| 11 | 14769293.37 | 383259.25 | 1895.15 | 193.52 | 3893.63 |
| 10 | 15181635.92 | 429868.63 | 1945.55 | 216.50 | 3997.18 |
| 9 | 15597019.69 | 486277.36 | 1995.95 | 244.25 | 4100.74 |

According to the current formation pressure, the binomial productivity equation (V) is constructed through the productivity test, and production is allocated according to the open flow.

P²−P_{wf}=Aq²+Bq (V)

In the formula, P-formation pressure, MPa; P_{wf}-shaft bottom flowing pressure, MPa; q-single well production, m³/d, A is 1.9633×10⁻⁸, B is 5.78×10⁻³;

In combination with the formula of the open flow,

$$\frac{- B + \sqrt{{B}^{2} + 4 A ( {P}^{2} - 0 . {1}^{2} )}}{2 A}$$

According to production allocation of ⅕ of the open flow, it is obtained that:

$$\frac{- B + \sqrt{{B}^{2} + 4 A ( {P}^{2} - 0 . {1}^{2} )}}{2 A} \qquad ( VI )$$

Therefore, before desorption of shale gas, the corresponding cumulative gas production and formation pressure and the corresponding production allocation results are shown in Table 3.

TABLE 3
Production allocation results of
shale gas before desorption

| Formation | Cumulative gas | production |
|---|---|---|
| pressure (MPa) | production (m³) | allocation (m³) |
| 42 | 2560459.197 | 68913.45 |
| 40 | 3336274.032 | 66309.87 |
| 38 | 4112330.293 | 63734.68 |
| 36 | 4888812.023 | 61191.45 |
| 34 | 5665925.73 | 58684.34 |
| 32 | 6443904.573 | 56218.18 |
| 30 | 7223013.614 | 53798.60 |
| 28 | 8003556.54 | 51432.18 |
| 26 | 8785884.367 | 49126.59 |
| 24 | 9570406.94 | 46890.82 |
| 22 | 10357608.4 | 44735.33 |
| 21 | 10752390.42 | 43691.43 |
| 20 | 11148068.55 | 42672.30 |
| 19 | 11544735.14 | 41679.76 |
| 18 | 11942493.03 | 40715.76 |
| 17 | 12341457.31 | 39782.38 |
| 16 | 12741757.64 | 38881.82 |
| 15 | 13143541.06 | 38016.41 |
| 14 | 13546975.68 | 37188.60 |
| 13 | 13952255.33 | 36400.97 |
| 12 | 14359605.84 | 35656.17 |
| 11 | 14769293.37 | 34956.94 |
| 10 | 15181635.92 | 34306.07 |
| 9 | 15597019.69 | 33706.35 |

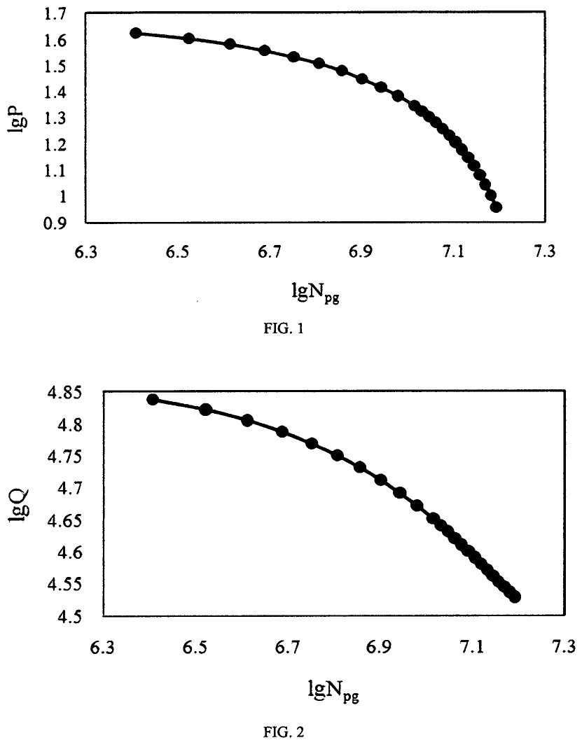

According to Table 3, the charts of cumulative gas production and formation pressure and single well allocation are drawn, as shown in FIG. 1 and FIG. 2;

When the formation pressure P<P_{cd}=8.67 MPa, shale gas begins to desorb, ignoring the surface volume corresponding to the cumulative water production on the left side of the equation. At this time, the actual material balance equation for a single well is established as equation (VII):

$${C}_{pg} {B}_{g} = {G}_{m} ( {B}_{g} - {B}_{gi} ) + {G}_{m} {B}_{gi} \frac{{c}_{w} {S}_{mwi}}{1 - {S}_{mwi}} ( {P}_{i} - P ) + {G}_{m} {B}_{gi} \frac{{c}_{m}}{1 - {S}_{mwi}} ( {P}_{i} - P ) + \frac{{G}_{m} {B}_{gi}}{( 1 - {S}_{mwi} ) {B}_{w}} {S}_{mwi} ( {R}_{si} - s ) {B}_{g} + {G}_{f} ( {B}_{g} - {B}_{gi} ) + {G}_{f} {B}_{gi} \frac{{c}_{w} {S}_{fwi}}{1 - {S}_{fwi}} ( {P}_{i} - P ) + {G}_{f} {B}_{gi} \frac{{c}_{f}}{1 - {S}_{mwi}} ( {P}_{i} - P ) + \frac{{G}_{f} {B}_{gi}}{( 1 - {S}_{fwi} ) {B}_{w}} {S}_{fwi} ( {R}_{s i} - {R}_{s} ) {B}_{g} + {ρ}_{s} {V}_{S} {V}_{m} ( \frac{{P}_{c d}}{{P}_{L} + {P}_{c d}} - \frac{P}{{P}_{L} + P} ) \qquad ( VII )$$

In the same way, the relevant parameters of shale gas are substituted into equation (VII), and the cumulative gas production is calculated according to different pressures, as shown in Table 4.

TABLE 4
Various parameter values of material balance after desorption

| | | | | Formation | | |
|---|---|---|---|---|---|---|
| | | Natural gas | | water | Rock | |
| | | elasticity | Formation | dissolution | elasticity | Adsorption |
| | Cumulative gas | gas | water elasticity | gas | gas | gas |
| Formation | production | production | gas production | production | production | production |
| pressure(MPa) | (m³) | (m³) | (m³) | (m³) | (m³) | (m³) |
| 8 | 483265353.97 | 556020.01 | 2046.36 | 278.48 | 4204.29 | 16411840.12 |
| 7.8 | 619871708.87 | 572003.66 | 2056.44 | 286.32 | 4225.00 | 21696963.85 |
| 7.6 | 754941375.89 | 588786.30 | 2066.52 | 294.54 | 4245.71 | 27177110.59 |
| 7.4 | 888361045.29 | 606430.54 | 2076.60 | 303.18 | 4266.42 | 32863277.88 |
| 7.2 | 1020007633.86 | 625005.73 | 2086.68 | 312.28 | 4287.13 | 38767305.99 |
| 7 | 1149747248.76 | 644588.96 | 2096.76 | 321.86 | 4307.84 | 44901960.20 |
| 6.8 | 1277434018.47 | 665266.15 | 2106.84 | 331.98 | 4328.55 | 51281022.94 |
| 6.6 | 1402908770.93 | 687133.35 | 2116.92 | 342.67 | 4349.27 | 57919397.18 |
| 6.4 | 1525997534.83 | 710298.32 | 2127.00 | 353.99 | 4369.98 | 64833222.63 |
| 6.2 | 1646509836.21 | 734882.36 | 2137.08 | 366.00 | 4390.69 | 72040006.79 |
| 6 | 1764236756.94 | 761022.54 | 2147.16 | 378.77 | 4411.40 | 79558772.94 |
| 5.8 | 1878948715.47 | 788874.30 | 2157.24 | 392.36 | 4432.11 | 87410227.86 |
| 5.6 | 1990392922.42 | 818614.74 | 2167.32 | 406.87 | 4452.82 | 95616952.23 |
| 5.4 | 2098290454.22 | 850446.51 | 2177.40 | 422.39 | 4473.53 | 104203617.55 |
| 5.2 | 2202332875.90 | 884602.58 | 2187.48 | 439.04 | 4494.24 | 113197233.83 |
| 5 | 2302178330.19 | 921352.26 | 2197.56 | 456.95 | 4514.95 | 122627433.43 |

According to the current formation pressure, production is allocated in combination with the binomial productivity equation (V) and according to the open flow, referring to Table 5 for the results.

TABLE 5
Production allocation
results after desorption

| Formation | | production |
|---|---|---|
| pressure | Cumulative gas | allocation |
| (MPa) | production (m³) | (m³) |
| 8 | 2560459.197 | 33160.58 |
| 7.8 | 619871708.9 | 33058.14 |
| 7.6 | 754941375.9 | 32957.98 |
| 7.4 | 888361045.3 | 32860.13 |
| 7.2 | 1020007634 | 32764.61 |
| 7 | 1149747249 | 32671.44 |
| 6.8 | 1277434018 | 32580.64 |
| 6.6 | 1402908771 | 32492.23 |
| 6.4 | 1525997535 | 32406.22 |
| 6.2 | 1646509836 | 32322.65 |
| 6 | 1764236757 | 32241.52 |
| 5.8 | 1878948715 | 32162.86 |
| 5.6 | 1990392922 | 32086.68 |
| 5.4 | 2098290454 | 32013.00 |
| 5.2 | 2202332876 | 31941.84 |
| 5 | 2302178330 | 31873.21 |

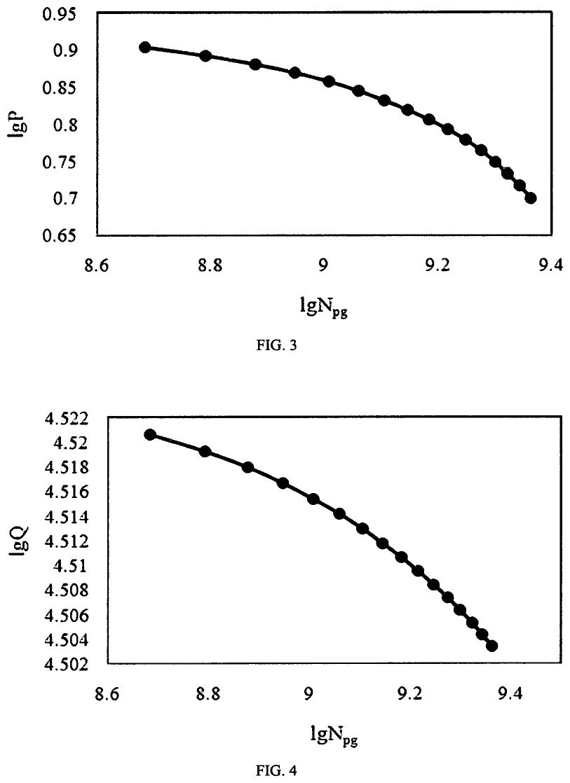

According to Table 5, the charts of cumulative gas production and formation pressure and single well allocation are drawn, as shown in FIG. 3 and FIG. 4;

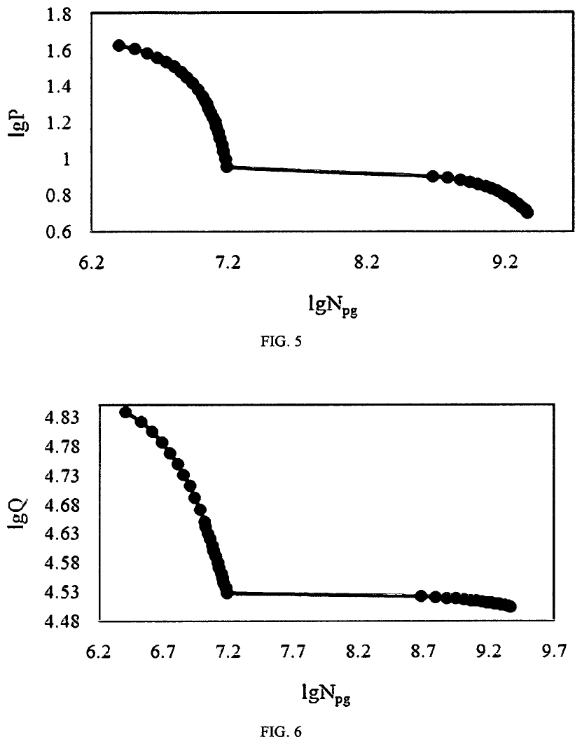

The full life cycle production allocating chart of the shale gas well is finally established in combination with the above charts, as shown in FIG. 5 and FIG. 6.

Finally, in the production process of a gas well, according to the current cumulative gas production of the well and the above charts, a reasonable production allocation amount is quickly determined.

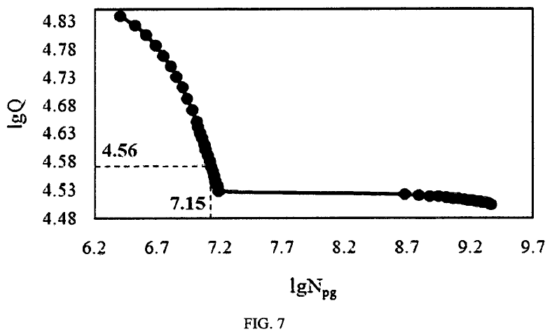

For example: the current cumulative gas production volume of the shale gas well is 0.14×10⁸ m³, and the cumulative gas production logarithm is 7.15. It can be known that the production allocation logarithm of the shale gas well is 4.56 by checking the chart (as shown in FIG. 7), so that the reasonable production allocation of the shale gas well is 36286 m³.

What is claimed is:

1. A shale gas well dynamic production allocating method, wherein the steps comprise:
step 1, constructing a single well material balance equation of a shale gas well, wherein
when the adsorbed gas is not desorbed, the material balance equation refers to formula (I);
$${G}_{pg} {B}_{g} + {G}_{pw} {B}_{w} = {G}_{m} ( {B}_{g} - {B}_{gi} ) + {G}_{m} {B}_{gi} \frac{{c}_{w} {S}_{mwi}}{1 - {S}_{mwi}} ( {P}_{i} - P ) + {G}_{m} {B}_{gi} \frac{{c}_{m}}{1 - {S}_{mwi}} ( {P}_{i} - P ) + \frac{{G}_{m} {B}_{gi}}{( 1 - {S}_{mwi} ) {B}_{w}} {S}_{mwi} ( {R}_{si} - {R}_{s} ) {B}_{g} + {G}_{f} ( {B}_{g} - {B}_{gi} ) + {G}_{f} {B}_{gi} \frac{{c}_{w} {S}_{fwi}}{1 - {S}_{fwi}} ( {P}_{i} - P ) + {G}_{f} {B}_{gi} \frac{{c}_{f}}{1 - {S}_{mwi}} ( {P}_{i} - P ) + \frac{{G}_{f} {B}_{gi}}{( 1 - {S}_{fwi} ) {B}_{w}} {S}_{fwi} ( {R}_{si} - {R}_{s} ) {B}_{g} \qquad ( I )$$
when the adsorbed gas is desorbed, the material balance equation refers to formula (II);
$${G}_{p g} {B}_{g} + {C}_{pw} {B}_{w} = {G}_{m} ( {B}_{g} - {B}_{gi} ) + {G}_{m} {B}_{gi} \frac{{c}_{w} {S}_{mwi}}{1 - {S}_{mwi}} ( {P}_{i} - P ) + {G}_{m} {B}_{gi} \frac{{c}_{m}}{1 - {S}_{mwi}} ( {P}_{i} - P ) + \frac{{G}_{m} {B}_{gi}}{( 1 - {S}_{mwi} ) {B}_{w}} {S}_{mwi} ( {R}_{si} - {R}_{s} ) {B}_{g} + {G}_{f} ( {B}_{g} - {B}_{gi} ) + {G}_{f} {B}_{gi} \frac{{c}_{w} {S}_{fwi}}{1 - {S}_{fwi}} ( {P}_{i} - P ) + {G}_{f} {B}_{gi} \frac{{c}_{f}}{1 - {S}_{mwi}} ( {P}_{i} - P ) + \frac{{G}_{f} {B}_{gi}}{( 1 - {S}_{fwi} ) {B}_{w}} {S}_{fwi} ( {R}_{si} - {R}_{s} ) {B}_{g} + {ρ}_{s} {V}_{S} {V}_{m} ( \frac{{P}_{c d}}{{P}_{L} + {P}_{c d}} - \frac{P}{{P}_{L} + P} ) \qquad ( II )$$
in formula (I) and formula (II):
Gₘ represents the surface free gas volume of shale gas reservoir matrix, G_{f} represents the surface free gas volume of shale gas reservoir fractures, B_{gi} represents the original volume coefficient of shale gas, C_{w} represents the groundwater compression coefficient of a shale gas reservoir, Cₘ represents the compression coefficient of shale matrix, Rₛᵢ represents the original groundwater solubility coefficient of a shale gas reservoir, Pᵢ represents the original formation pressure, S_{wf} represents the fracture water saturation of a shale gas reservoir, C_{f} represents the fracture rock compressibility coefficient, B_{w} represents the formation water volume coefficient, ρₛ represents the shale density, Vₘ represents the Langmuir's volume, P_{L} represents the Langmuir's pressure, P_{cd} represents the critical desorption pressure, Vₛ represents the single well controlled shale volume, B_{g} represents the natural gas volume coefficient, Rₛ represents the formation water solubility coefficient, Rₛ represents the original groundwater solubility coefficient, P represents the formation pressure, G_{pg} represents the cumulative gas production, G_{pw} represents the cumulative water production, S_{mwi} represents the original water saturation of the matrix, and S_{fwi} represents the original water saturation of the fracture;
step 2, according to the actual shale gas well related reservoir properties, establishing the relationship function between the cumulative gas production and the formation pressure in combination with constructing a single well actual material balance equation in step 1;
step 3, calculating the cumulative gas production according to the current formation pressure;
step 4, according to the current formation pressure, through the productivity test, establishing a binomial productivity equation, and allocating production according to the open flow;
step 5, according to the production allocating result obtained in step 4, drawing a chart of cumulative gas production and formation pressure and single well production allocation; and
step 6, according to the cumulative gas production of different reservoirs of a shale gas well, searching for the resulting chart for production allocation.

2. The shale gas well dynamic production allocating method according to claim 1, wherein: the chart drawn in step 5 comprises a double-logarithmic diagram of pressure and cumulative gas production before desorption, a double-logarithmic diagram of production allocation and cumulative gas production before desorption, a double-logarithmic diagram of pressure and cumulative gas production after desorption, a double-logarithmic diagram of production allocation and cumulative gas production after desorption, and the full life cycle production allocating chart of a shale gas well is drawn based on these four charts.
